(19) United States
(12) Patent Application Publication
(10) Pub. No.: US 2012/0211873 A1
(43) Pub. Date: Aug. 23, 2012

(54) METHOD FOR FORMING A PATTERN AND SEMICONDUCTOR DEVICE

(75) Inventors: Kenichi OYAMA, Nirasaki City (JP); Hidetami YAEGASHI, Tokyo (JP)

(73) Assignee: TOKYO ELECTRON LIMITED, Tokyo (JP)

(21) Appl. No.: 13/402,547

(22) Filed: Feb. 22, 2012

(30) Foreign Application Priority Data
Feb. 23, 2011 (JP) 2011-37158

(51) Int. Cl. H01L 29/02; H01L 21/31

(52) U.S. Cl. 257/632; 438/700; 257/E29.002; 257/E21.24

(57) ABSTRACT

A method for forming a pattern includes: forming a resist film on an object and patterning the formed resist film; forming a spacer film to coat the object and the resist film, and forming a concave portion surrounded by the spacer film; forming a first opening from the concave portion by etching a portion of the spacer film so that the spacer film remains beside a side wall of the resist film while exposing the object under the concave portion and the top surface of the resist film; and forming a second opening by removing the resist film.

### CROSS-REFERENCE TO RELATED APPLICATIONS

This application claims the benefit of Japanese Patent Application No. 2011-037158, filed on Feb. 23, 2011, in the Japan Patent Office, the disclosure of which is incorporated herein in its entirety by reference.

### TECHNICAL FIELD

The present disclosure relates to a method for forming a pattern of a hole or trench on a substrate, and a semiconductor device manufactured by the same.

### BACKGROUND

With high integration of semiconductor devices, a technology for processing semiconductor devices in a finer manner has been needed. As a technology for providing fine patterns for semiconductor devices, a method of forming a resist pattern using a photolithographic process and etching a base film using the resist pattern as a mask has been commonly used.

Recently, however, making semiconductor devices fine beyond the resolution limit of a photolithographic process has been desired. In addition, for an exposure technology, it has been said that the resolution of ArF immersion exposure, which has been widely used in exposure technology, reaches a limit of 4×nm generations.

In order to achieve a finer 3×nm generation, a double patterning technology such as a lithography etching lithography etching (LELE) process or the like has been actively developed. For example, a process is known in which a first resist opening pattern of a first resist film is formed and a first hole or trench pattern is formed on a base film using the formed first resist opening pattern, and, subsequently, a second resist opening pattern of a second resist film is formed and a second hole or trench pattern is formed on the base film using the formed second resist opening pattern.

However, the LELE process of forming resist patterns using double patterning has the following problems.

In the LELE process, the first resist opening pattern is formed by means of a coating and developing apparatus, and the first hole or trench pattern is formed by means of an etching apparatus. Thereafter, the second resist opening pattern is formed by means of the coating and developing apparatus, and the second hole or trench pattern is formed by means of the etching apparatus. This leads to an increase in the number of processes. In addition, a photolithographic process has to be performed twice, which results in an increase in the total process costs.

### SUMMARY

The present disclosure provides a method for forming a fine hole or trench pattern with a number of processes less than that of the convention LELE process, without using a photolithographic process twice, and a semiconductor device manufactured by the method.

According to one embodiment of the present disclosure, there is provided a method for forming a pattern comprising: forming a resist film on an object and patterning the formed resist film; forming a spacer film to coat the object and the resist film, and forming a concave portion surrounded by the spacer film; forming a first opening from the concave portion by etching a portion of the spacer film so that the spacer film remains beside a side wall of the resist film while exposing the object under the concave portion and the top surface of the resist film; and forming a second opening by removing the resist film.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A and 1B are views for explaining a method for forming a pattern of a hole or trench according to an embodiment, showing an example of a substrate structure in a process.

FIG. 2A to 2C are views for explaining the method for forming a pattern of a hole or trench according to the embodiment, showing an example of the substrate structure in a process.

FIG. 3A to 3C are views for explaining the method for forming a pattern of a hole or trench according to the embodiment, showing an example of the substrate structure in a process.

FIG. 4A to 4C are views for explaining the method for forming a pattern of a hole or trench according to the embodiment, showing an example of the substrate structure in a process.

FIG. 5A to 5C are views for explaining the method for forming a pattern of a hole or trench according to the embodiment, showing an example of the substrate structure in a process.

FIG. 6A to 6C are views for explaining the method for forming a pattern of a hole according to the embodiment, showing a SEM image in each process.

FIG. 7A to 7C are views for explaining the method for forming a pattern of a trench according to the embodiment, showing a trench pattern layout and a SEM image in each process.

### DETAILED DESCRIPTION

An embodiment of the present disclosure will now be described in detail with reference to the drawings.

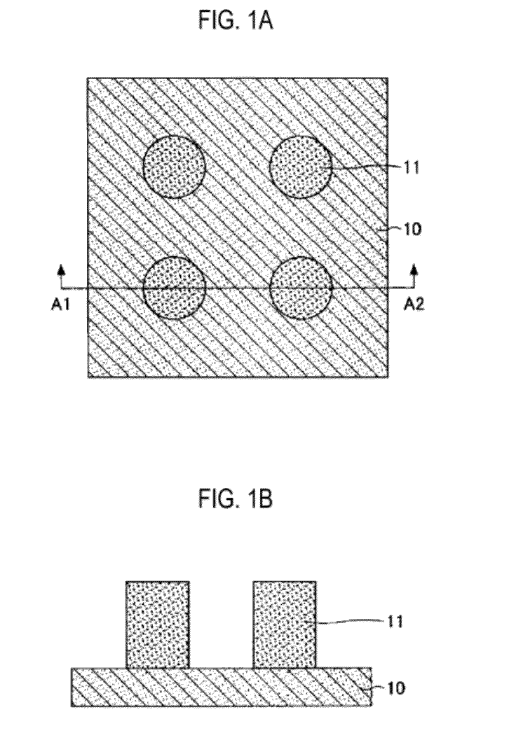

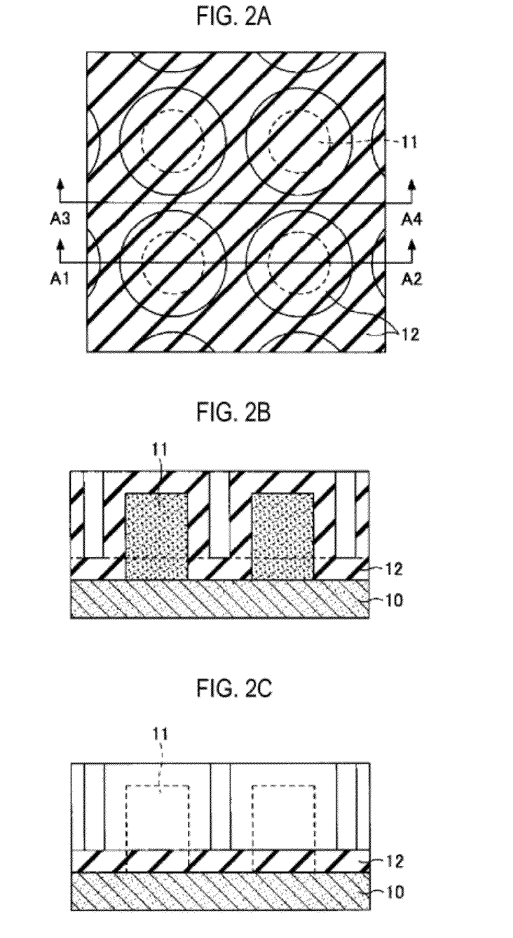

FIGS. 1 to 5 are schematic views for explaining a method for a forming a pattern according to an embodiment, showing examples of a substrate structure in each process. FIGS. 1A, 2A, 3A, 4A and 5A are plan views showing examples of the substrate structure in each process. FIGS. 1B, 2B, 3B, 4B and 5B are sectional views taken along line A1-A2 of FIGS. 1A, 2A, 3A, 4A and 5A, respectively. FIGS. 2C, 3C, 4C and 5C are sectional views taken along line A3-A4 of FIGS. 2A, 3A, 4A and 5A, respectively.

Although it is shown in FIGS. 1 to 5 that one kind of base film formed on a substrate (not shown) is used as an object, the present disclosure is not limited thereto. For example, the present disclosure may employ a stacked structure of one or more kinds of base films, each of which is made of a material exemplified below.

The material of the base film may be, but is not limited to, tetraethoxysilane (TEOS), spin-on-glass (SOG), SiON, a composite of low temperature oxide (LTO) and BARC (i.e.,

SiARC, which is Si-contained BARC), etc.

### <Resist Film Forming Process>

FIGS. 1A and 1B show an example of the substrate structure after a resist film is formed thereon according to the method for forming a pattern of the present disclosure. In the resist film forming process, a resist film 11 is formed on a base film and is patterned into a predetermined pattern.

Specifically, the resist film 11 is first formed on a base film 10 by spin-on using, for example, a coating and developing apparatus having an exposure device. The material of the resist film 11 may be an ArF resist. Then, the formed resist film 11 is patterned by photolithography using, for example, the coating and developing apparatus having an exposure device. The film thickness and patterning pitch in the resist film formation may be appropriately selected by those skilled in the art.

### <Spacer Film Forming Process>

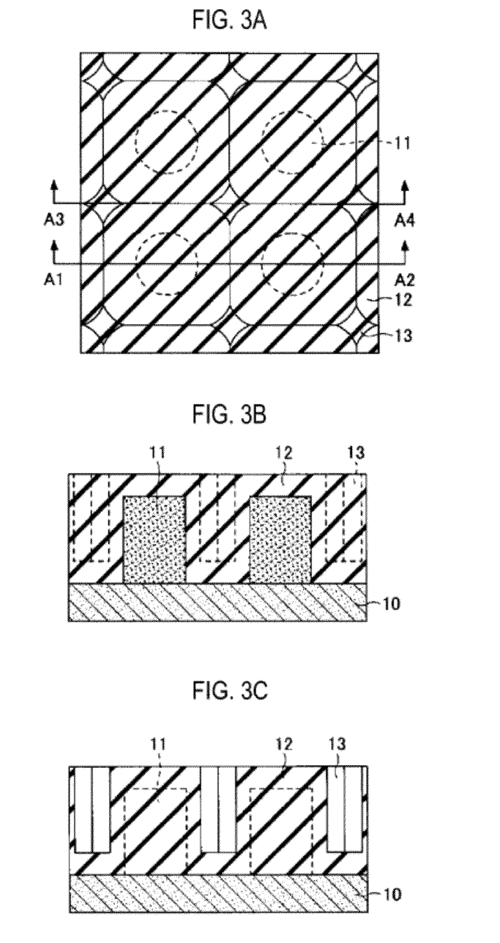

Next, a process of forming a spacer film 12 to coat the base film 10 on which the resist film 11 is formed will be described. FIGS. 2 and 3 show an example of the substrate structure during and after the spacer film forming process, respectively.

The material of the spacer film 12 may be, but is not limited to, silicon oxide (SiO₂), aluminum oxide (AlₓO_{y}), aluminum nitride (AlN), titanium oxide (TiOₓ), silicon nitride (SiN), amorphous silicon, polysilicon and a combination thereof.

The spacer film forming process is not particularly limited but may be preferably an atomic layer deposition (ALD). ALD refers to a method of forming a film having high step coverage through repetition of an absorption of raw material compound molecules onto a surface of each monolayer on a substrate, a film formation by a reaction, and a reset of the system. For example, the spacer film forming process generally alternates between a process of supplying silicon-containing raw material gas into a process container of a film forming apparatus and absorbing silicon raw material onto the substrate, and a process of supplying oxygen-containing gas into the process container and oxidizing the silicon raw material, which will be described in detail below.

ALD is advantageous in that it can provide a high precision of film thickness control, composition control and step coverage and further provide a wide range of choices of available materials. In addition, it has another advantage in that it allows a film to be formed in a range of temperatures at which other manufacturing processes of semiconductor devices are performed, for example, a temperature range of 23 to 25 degrees C. A method for forming a SiO₂ film using ALD will be described below.

In the process of absorbing the silicon-containing raw material gas onto the substrate, aminosilane gas having two amino groups per one molecule thereof (for example bistertiarybutylaminosilane (BTBAS)) as the silicon-containing raw material gas is supplied into the process container through a supplying nozzle of the silicon-containing raw material gas for a predetermined period of time T1. Thus, BTBAS is absorbed onto the substrate. The period of time T1 may be set to, for example, 1 to 60 sec. A flow rate of the silicon-containing raw material gas may be set to 10 to 50 mL/min (sccm). An internal pressure of the process container may be set to 13.3 to 665 Pa. These parameters may be appropriately selected by those skilled in the art depending on the type and thickness of films to be formed.

Next, in the process of supplying the oxygen-containing gas into the process container and oxidizing the silicon raw material, for example, O₂ gas plasmarized by a plasma generating mechanism having a high frequency power source, as the oxygen-containing gas, is supplied into the process container through a gas supplying nozzle for a predetermined period of time T2. Thus, the BTBAS absorbed onto the substrate is oxidized to form the SiO₂ film. The period of time T2 may be set to, for example, 5 to 300 sec. A flow rate of the oxygen-containing gas may be set to 100 to 2000 mL/min (sccm). A frequency of the high frequency power source may be set to 13.56 MHz and power of the high frequency power source may be set to 5 to 1000 W. The internal pressure of the process container may be set to 13.3 to 665 Pa. These parameters may be appropriately selected by those skilled in the art.

In addition, between the process of absorbing the silicon-containing raw material gas onto the substrate and the process of oxidizing the silicon raw material, vacuumizing the interior of the process container and supplying a purge gas formed of an inert gas such as, for example, N₂ gas or the like, into the process container may be performed for a predetermined period of time T3. The period of time T3 may be set to, for example, 1 to 60 sec. A flow rate of the purge gas may be set to 50 to 5000 mL/min (sccm). These parameters may be appropriately selected by those skilled in the art. In this process, as long as residual gas is removed from the process container, the vacuumization may be performed under a state where all gases including the purge gas are not supplied.

The BTBAS is an aminosilane gas having two amino groups per one molecule thereof that is used as the silicon-containing raw material gas. In addition to BTBAS, the aminosilane gas may be bisdiethylaminosilane (BDEAS), bisdimethylaminosilane (BDMAS), diisopropylaminosilane (DIPAS) and bisethylmethylaminosilane (BEMAS). Further, an aminosilane gas having three or more amino groups per one molecule thereof or an aminosilane gas having one amino group per one molecule thereof can be used as the silicon-containing raw material gas.

Further, in addition to O₂ gas, the oxygen-containing gas may include NO gas, N₂O gas, H₂O gas and O₃ gas, which may be plasmarized by a high frequency electric field to form oxidizing agents. The use of such plasmarized oxygen-containing gas allows the SiO₂ film to be formed at a low temperature of 300 degrees C. or less. In addition, the SiO₂ film can be formed at a temperature of 100 degrees C. or less or room temperature by adjusting the flow rate of the oxygen-containing gas, the power of the high frequency power source and the internal pressure of the process container.

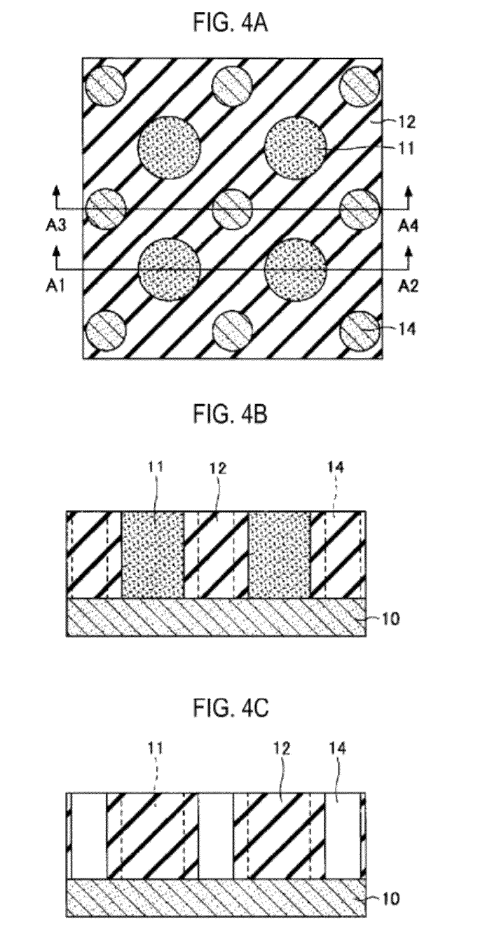

According to the film forming process described above, the spacer film 12 is formed to cover the resist film 11 and the base film 10. In other words, the spacer film 12 is formed to form a pillar having the resist film 11 as a core material. Thus, as the spacer film 12 is formed, a concave portion 13 surrounded by a plurality of pillars, each of which is made of the spacer film 12 and the resist film 11, is formed. The size of the concave portion 13 may be appropriately selected by those skilled in the art since it is dependant on the patterning of the resist film 11 and the thickness of the spacer film 12. In addition, although the shape of the concave portion 13 also depends on the patterning of the resist film 11 and the thickness of the spacer film 12, it is shown to be circular in FIG. 4A and subsequent figures since it may be rounded by the subsequent etching process, but is not limited thereto.

### <First Opening Forming Process>

Next, a process of forming a first opening will be described. FIGS. 4A to 4C show an example of the substrate structure after the process of forming the first opening.

First, a portion of the spacer film 12 is anisotropically etched so that the spacer film 12 remains beside a side wall of the resist film 11 and the spacer film 12 does not form the bottom of the concave portion. The etching method used may be, but is not limited to, a reactive ion etching (RIE). Thus, the spacer film 12 forming the bottom of the concave portion 13 as well as the spacer film above the top of the resist film 11 is removed and a hole or trench pattern as the first opening 14 is formed on the base film 10.

If the spacer film 12 is made of SiO₂, TiOₓ, SiN, amorphous silicon, polysilicon or the like, the etchant gas may be a mixture of CF-based gas such as CF₄, C₄F₈, CHF₃, CH₃F, CH₂F₂ or the like and Ar gas. Further, oxygen can be added to this mixture, if needed. If the spacer film 12 is made of, for example, AlₓO_{y}, MN or TiOₓ, the etchant gas may be a so-called halogen-based gas such as Cl₂, Cl₂+HBr, Cl₂+O₂, CF₄+O₂, SF₆, Cl₂+N₂, Cl₂+HCl, HBr+Cl₂+SF₆ or the like.

The etching process may be performed using a plasma etching apparatus including a process container, a gas supplying unit which supplies a process gas into the process container, and a holder which holds a substrate placed in the process container. In the process container, an upper electrode to which high frequency power can be applied is disposed above the holder acting as a lower electrode to which high frequency power can be applied. With the substrate held by the holder, for example, CF₄ gas, O₂ gas and Ar gas are supplied from the gas supplying unit into the process container and the interior of the process container is kept at a pressure of, for example, 40 mTorr. Thereafter, a high frequency power of, for example, 1000 W, having a frequency of 60 MHz, is applied to the upper electrode to plasmarize the process gas, while a high frequency power of, for example, 300 W, having a frequency of 13.56 MHz as a bias frequency, is applied to the lower electrode. Thus, the spacer film is etched.

### <Second Opening Forming Process>

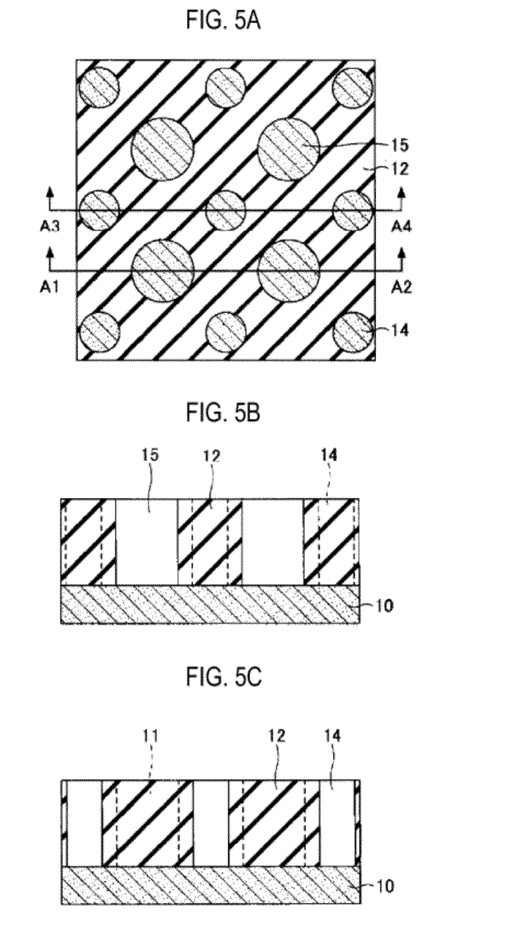

Next, a process of forming a second opening will be described. FIGS. 5A to 5C show an example of the substrate structure after the process of forming the second opening.

In this process, the resist film 11 is removed. The method for removing the resist film 11 may be, but is not limited to, ashing and etching. Thus, a hole or trench pattern as the second opening 15 is formed in a region from which the resist film 11 is removed.

If the resist film is to be removed by etching, an etching rate of the resist film 11 for the etchant gas used is preferably larger than an etchant rate of the spacer film 12 for the etchant gas used. In this case, the selectivity, which is a ratio of the etching rate of the resist film 11 to the etching rate of the spacer film 12, is increased and the spacer film 12 is slightly etched when the resist film 11 is etched. Thus, the spacer film 12 can be left with a high precision of shape when the resist film 11 is etched.

If a plurality of base films 10 is already formed on the substrate, a base film 10 forming the bottom of a first or second hole or trench pattern may be etched in the subsequent process.

Next, an embodiment relating to the formation of a hole or trench pattern using a process of the present disclosure will be described.

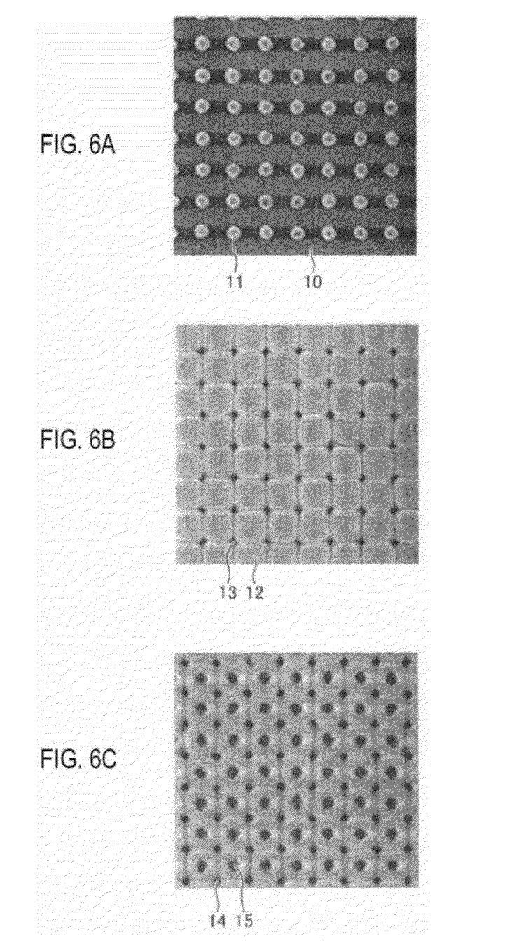

FIGS. 6A to 6C are views for explaining the hole pattern forming method according to this embodiment, showing a SEM image in each process. All SEM images in this embodiment were taken using a Hitachi high resolution FEB measuring device CG4000 (available from Hitachi High Technologies Kabushiki Kaisha).

FIG. 6A shows a SEM image after the resist film forming process. In this embodiment, a half pitch hp1 of the resist film is 44 nm. FIG. 6B shows a SEM image after the spacer film forming process, from which it can be seen that a SiO₂ film is formed as the spacer film 12 by ALD and the concave portion 13 surrounded by pillars of SiO₂ is formed. FIG. 6C shows a SEM image after the second opening (hole pattern) forming process, from which it can be seen that a hole pattern having a half pitch of 31 nm is formed according to an embodiment of the present disclosure.

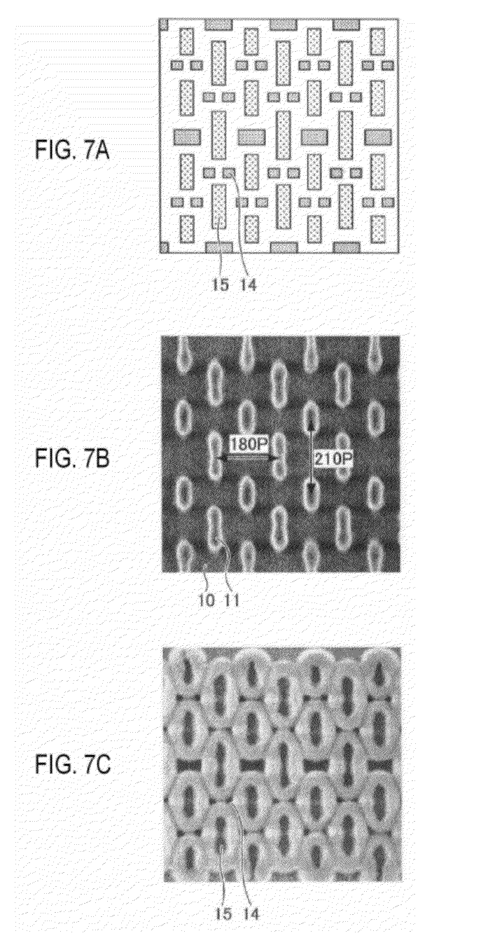

FIGS. 7A to 7C are views for explaining a trench pattern forming method according to another embodiment of the present disclosure. FIG. 7A schematically shows a first opening 14 and a second opening 15 for a trench pattern which has been actually obtained. The trench pattern of this embodiment is not limited to the trench pattern of FIG. 7A but may be appropriately selected by those skilled in the art.

When forming the trench pattern as shown in FIG. 7A, in a conventional LELE process, an opening pattern of a first resist film is formed and this formed-first resist opening pattern is used to form a first opening on the base film. Subsequently, an opening pattern of a second resist film is formed and this formed-second resist opening pattern is used to form a second opening on the base film. This leads to an increase in the number of processes. In addition, the two resist opening patterns require a photolithography process to be performed twice, which results in an increase in costs.

In contrast, in the pattern forming method of the present disclosure, a resist pattern made of a resist film is formed in a pattern to which the second opening 15 corresponds. Thereafter, a spacer film is formed to coat a base film and the resist film. A trench pattern can be simply formed using a concave portion, which is surrounded by the formed spacer film, and the resist pattern.

In the trench pattern of FIG. 7A, unlike the above-described hole pattern, the first opening 14 is different in shape from the second opening 15 when viewed from above. In addition, the first openings 14 have two different shapes when viewed from above. In this manner, using the trench pattern forming method of the present disclosure, it is possible to control the shapes of the pattern of the first opening, which does not directly transfer the pattern in the patterning of the resist film, as well as the second opening, which directly transfers the pattern in the patterning of the resist film.

FIGS. 7B and 7C show an example of the actually formed trench pattern of FIG. 7A. FIG. 7B shows a SEM image after the resist film forming process and FIG. 7C shows a SEM image after the second opening (trench pattern) forming process. The method of the present disclosure makes it possible to easily form the complicated trench pattern shown in FIGS. 7A to 7C. That is, the trench pattern can be formed with a decreased number of processes relative to the conventional LELE process. In addition, there is no need to perform a photolithography process twice, which results in a reduction in costs as compared with the conventional LELE process.

According to the present disclosure, it is possible to provide a method for forming a fine hole or trench pattern with a number of processes less than that of the convention LELE process, without using a photolithographic process twice.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for forming a pattern comprising:
forming a resist film on an object and patterning the formed resist film;
forming a spacer film to coat the object and the resist film, and forming a concave portion surrounded by the spacer film;
forming a first opening from the concave portion by etching a portion of the spacer film so that the spacer film remains beside a side wall of the resist film while exposing the object under the concave portion and the top surface of the resist film; and
forming a second opening by removing the resist film.

2. The method of claim 1, wherein the first opening is different in shape from the second opening.

3. The method of claim 1, wherein a plurality of the first openings is formed and the first openings have two or more different shapes.

4. The method of claim 1, wherein the spacer film is made of one or more selected from a group comprising silicon oxide, aluminum oxide, aluminum nitride, titanium oxide, silicon nitride, amorphous silicon and polysilicon.

5. The method of claim 1, wherein the spacer film is formed by an ALD process.

6. A semiconductor device manufactured according to the method of claim 1.
